(19) United States
(12) Patent Application Publication
(10) Pub. No.: US 2026/0338542 A1
(43) Pub. Date: Oct. 29, 2026

(54) INSPECTION APPARATUS, METHOD OF INSPECTION USING THE INSPECTION APPARATUS, AND ELECTRONIC DEVICE INSPECTED BY THE INSPECTION APPARATUS

(71) Applicant: SAMSUNG DISPLAY CO., LTD., YONGIN-SI (KR)

(72) Inventors: JONGHWAN LEE, Yongin-si (KR); BYEONGCHUN LEE, Yongin-si (KR); SANGHUN LEE, Yongin-si (KR); YONG JUN PARK, Yongin-si (KR)

(21) Appl. No.: 19/428,608

(22) Filed: Dec. 22, 2025

(30) Foreign Application Priority Data
Apr. 24, 2025 (KR) 10-2025-0053602

(51) Int. Cl. G01B 11/06; C23C 16/52; H10P 72/76

(52) U.S. Cl. CPC G01B 11/0616; C23C 16/52; H10P 72/7612; H10P 72/7614

(57) ABSTRACT

An inspection apparatus includes a transfer chamber, a transfer actuator, a plurality of lift pins disposed under the transfer actuator, supporting the substrate, and spaced apart from the transfer actuator, a plurality of auxiliary pins disposed under transfer actuator, supporting the substrate in the second direction, surrounding the test element of the substrate in the plan view, and symmetrically disposed about the test element, and a thickness sensor including a plurality of probes which are disposed at one side of the transfer chamber and measure a thickness of the thin film deposited on the test element of the substrate.

### CROSS-REFERENCE TO RELATED APPLICATION

This application claims priority under 35 U.S.C. § 119 to Korean Patent Application No. 10-2025-0053602, filed on Apr. 24, 2025 in the Korean Intellectual Property Office (KIPO), the entire contents of which are hereby incorporated by reference.

### TECHNICAL FIELD

The present disclosure relates to inspection and, more particularly, to an inspection apparatus, a method of inspection using the inspection apparatus, and an electronic device inspected by the inspection apparatus.

### DISCUSSION OF THE RELATED ART

In a manufacturing process of a display device, a transistor layer may be formed on a substrate through various film formation processes and etching processes, and an organic light-emitting layer including a lower electrode, an organic film layer (e.g., a hole transport layer, a light-emitting layer, and an electron transport layer), and an upper electrode may be formed on the transistor layer. Subsequently, the display device may be completed by encapsulating the substrate on which the transistor layer and the organic light-emitting layer are formed using an encapsulation thin film.

After the encapsulation thin film is used to encapsulate the display device substrate, an inspection step may be performed to determine whether the encapsulation thin film has been deposited to a predetermined thickness. Where the display device is supported by lift pins during inspection, sagging may occur in the display device, which may reduce the reliability of the thickness measurement of the encapsulation thin film.

### SUMMARY

An inspection apparatus includes a transfer chamber through which a substrate including a test element and a thin film deposited on an upper surface of the test element is transferred. A transfer actuator is disposed in the transfer chamber and is configured to transfer the substrate in a first direction. A plurality of lift pins are disposed under the transfer actuator in a cross-sectional view. The lift pins are configured to support the substrate in a second direction intersecting the first direction, and are spaced apart from the transfer actuator in a plan view. A plurality of auxiliary pins are disposed under transfer actuator in the cross-sectional view, are configured to support the substrate in the second direction, surround the test element of the substrate in the plan view, and are symmetrically disposed about the test element. A thickness sensor including a plurality of probes which are disposed at one side of the transfer chamber are configured to measure a thickness of the thin film deposited on the test element of the substrate.

Each of the auxiliary pins may be spaced apart from the test element by a distance from about 20 nm to about 80 nm, in the plan view.

The auxiliary pins may be spaced apart from the transfer actuator in the plan view.

The number of the auxiliary pins may be within a range from 4 to 80.

The test element may include a first test element and a second test element spaced apart from the first test element in the plan view, and the auxiliary pins may include a first auxiliary pin symmetrically disposed about the first test element and a second auxiliary pin symmetrically disposed about the second test element.

The number of each of the first auxiliary pin and the second auxiliary pin may be within a range from 4 to 8.

The inspection apparatus may further include a first process chamber positioned at one side of the transfer chamber and a second process chamber positioned at another side of the transfer chamber.

The first process chamber may be configured for depositing an inorganic film and the second process chamber may be a process chamber configured for depositing an organic film.

The thickness sensor may be configured for measuring either an inorganic film or an organic film.

The number of the test element may be within a range of from 1 to 10, and the probes of the thickness sensor may correspond one-to-one to the test element of the substrate.

The thickness sensor may be configured to cast light through the probes.

A method of inspection according to embodiments of the present disclosure includes depositing a thin film on a substrate, that includes a test element, in a first process chamber. The substrate is transferred to a transfer chamber through a transfer actuator. The substrate is lifted using a plurality of lift pins that are spaced apart from the transfer actuator in the plan view and a plurality of auxiliary pins surrounding the test element and symmetrically disposed about the test element. A thickness of the thin film deposited on the test element of the substrate is measured using a thickness sensor.

The lifting of the substrate may be performed using the lift pins and the auxiliary pins. Each of the auxiliary pins may be spaced apart from the test element of the substrate by a distance within a range of about 20 nm to about 80 nm, in the plan view.

After the lifting the substrate using the lift pins and the auxiliary pins, an angle formed between one side of the substrate and a horizontal reference plane may less than or equal to about 1.5 degrees.

In the measuring of the thickness of the thin film, the thickness sensor may measure the thickness of the thin film by casting light on the test element of the substrate.

After the measuring of the thickness of the thin film, the method of inspection may further include transferring the substrate to a second process chamber when the thickness of the thin film is equal to a preset thickness.

After the transferring the substrate to the second process chamber, the method of inspection may further include removing a test area on which the test element of the substrate is disposed.

The first process chamber may be a process chamber for depositing an inorganic film and the second process chamber may be a process chamber for depositing an organic film.

After the transferring the substrate to the second process chamber, the method of inspection may further include returning the substrate to the first process chamber when the thickness of the thin film is different from a preset thickness.

An electronic device includes a display device and a processor configured to drive the display device. The inspection apparatus is configured to measure the display device. The inspection apparatus includes a transfer chamber through which a substrate including a test element and a thin film deposited on an upper surface of the test element is transferred, a transfer actuator which is disposed in the transfer chamber and is configured to transfer the substrate in a first direction, a plurality of lift pins disposed under the transfer actuator in a cross-sectional view, configured to support the substrate in a second direction intersecting the first direction, and spaced apart from the transfer actuator in a plan view, a plurality of auxiliary pins disposed under transfer actuator in the cross-sectional view, configured to support the substrate in the second direction, surrounding the test element of the substrate in the plan view, and symmetrically disposed about the test element, and a thickness sensor including a plurality of probes which are disposed at one side of the transfer chamber and are configured to measure a thickness of the thin film deposited on the test element of the substrate.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a schematic view illustrating a substrate inspection apparatus according to an embodiment of the present disclosure.

FIG. 2 is a cross-sectional view illustrating an embodiment of a first transport chamber of FIG. 1.

FIGS. 3, 4, and 5, are plan views illustrating lift pins, auxiliary pins of the first transfer chamber, and a substrate of FIG. 2.

FIG. 6 is a plan view illustrating an enlarged view of a first auxiliary pin area of FIG. 5.

FIG. 7 is a cross-sectional view illustrating an embodiment in which lift pins and auxiliary pins of FIG. 2 support the substrate.

FIG. 8 is an enlarged view of area A of FIG. 7.

FIG. 9 is a cross-sectional view illustrating an embodiment of a display panel including the substrate of FIG. 7.

FIG. 10 is a cross-sectional view illustrating an embodiment in which a test area is removed from the display panel of FIG. 9.

FIG. 11 is a flowchart illustrating an embodiment of a method of inspecting the substrate of the substrate inspection apparatus of FIG. 1.

FIG. 12 is a block diagram illustrating an electronic device according to an embodiment of the present disclosure.

FIG. 13 is a schematic diagram of an electronic device according to various embodiments of FIG. 12.

### DETAILED DESCRIPTION OF THE EMBODIMENTS

In describing embodiments of the present disclosure illustrated in the drawings, specific terminology is employed for sake of clarity. However, the present disclosure is not necessarily intended to be limited to the specific terminology so selected, and it is to be understood that each specific element includes all technical equivalents which operate in a similar manner.

The present disclosure may be modified in various ways and may have various forms, and specific embodiments are illustrated in the drawings and described in detail in the specification. However, this is not necessarily intended to limit the present disclosure to specific disclosed forms, and it should be understood to include all modifications, equivalents, or alternatives falling within the spirit and scope of the present disclosure.

Terms such as first and second may be used to describe various elements, but the elements should not necessarily be limited by the terms. The terms may be used for the purpose of distinguishing one element from another element. For example, a first element may be named as a second element without departing from the scope of the present disclosure, and similarly, the second element may also be named as the first element.

When an element is referred to as being "connected to" another element, it should be understood that the element may be directly connected or coupled to the other element, but that another element may also exist in between. Other expressions used to describe relationships between elements, that is, "between" and "immediately between" or "adjacent to" and "directly adjacent to" should be interpreted in the same manner.

Singular expressions include plural expressions unless the context clearly indicates otherwise. In the present application, the terms such as "include" or "have" are intended to specify the presence of the features, numbers, steps, operations, elements, components, or combinations thereof, but should not necessarily be construed to preclude the possibility of the presence or addition of one or more other features, numbers, steps, operations, elements, components, or combinations thereof.

Terms such as "below," "beneath," "under," "underneath," "above," "over," "upper," and "on" are used to describe relative relationships of components shown in the drawings. The terms are relative concepts and are described based on the directions shown in the drawings.

Hereinafter, embodiments of the present disclosure will be described in more detail with reference to the accompanying drawings. The same reference numerals are used for the same components in the drawings, and to the extent that an element is not described in detail with respect to this figure, it may be understood that the element is at least similar to a corresponding element that has been described elsewhere within the present disclosure.

Embodiments of the present disclosure relates to an inspection apparatus for measuring the thickness of a thin film deposited on a substrate in a display device manufacturing process. The apparatus includes a transfer chamber through which the substrate is moved, a transfer part that carries the substrate along a first direction, and a plurality of lift pins and auxiliary pins that support the substrate from below in a second direction. The auxiliary pins are symmetrically disposed about one or more test elements formed on the substrate and are spaced from the transfer part in a plan view. A measuring part located at one side of the transfer chamber includes multiple probes that cast light toward the test elements to measure the thickness of the deposited thin film. By arranging the auxiliary pins at a precise distance, such as approximately 20 mm to 80 mm, from the test elements, the substrate is evenly supported during inspection, minimizing sagging or bending that could distort thickness measurements.

The apparatus may operate as part of an in-line inspection method that occurs between deposition processes. A first process chamber deposits an inorganic or organic thin film, and the substrate is transferred to the inspection chamber for thickness measurement before proceeding to a second process chamber. If the measured thickness differs from a preset standard, the substrate can be returned for re-processing, avoiding yield loss and wasted production time. The method includes lifting the substrate using the combination of lift pins and auxiliary pins to maintain an angle within approximately 1.5° relative to the horizontal plane, ensuring measurement accuracy. Light from the probes reflects off the test elements to enable optical detection of film thickness, and the results are used to control subsequent process steps.

Embodiments of the present disclosure may also encompasses a display device inspected by the apparatus and an electronic device incorporating the display device, such as smartphones, laptop/tablet computers, computer monitors, or automotive displays. By providing additional mechanical support and enabling in-process optical measurement, the apparatus enhances the reliability and efficiency of thin-film inspection during production. It allows early detection of deposition errors, reduces the likelihood of defective panels proceeding through subsequent manufacturing stages, and increases throughput. Overall, embodiments of the present disclosure improves both accuracy and cost-effectiveness in thin-film quality control for advanced display fabrication.

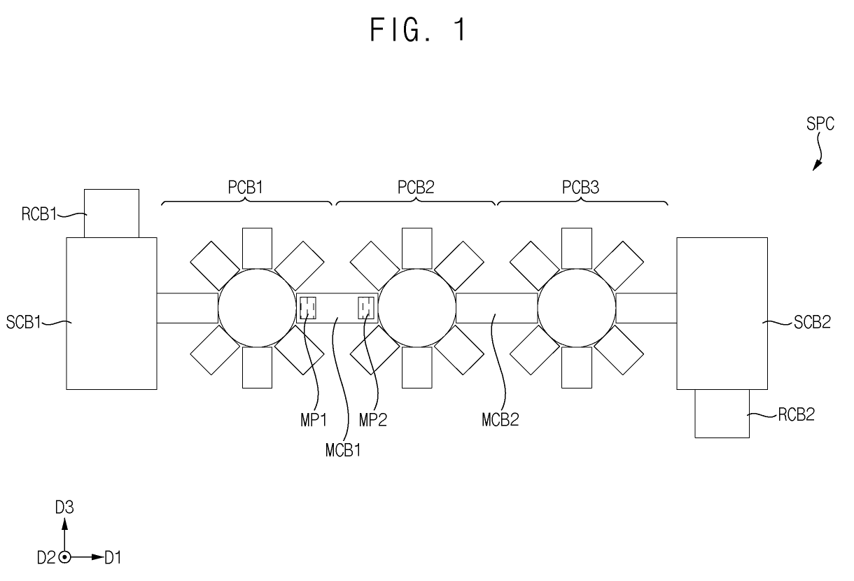

FIG. 1 is a schematic view illustrating a substrate inspection apparatus according to an embodiment of the present disclosure.

In the present specification, a plane may be defined by a first direction D1 and a second direction D2 intersecting the first direction D1. For example, the second direction D2 may be perpendicular to the first direction D1. In addition, a third direction D3 may be a normal direction of the plane. For example, the third direction D3 may be perpendicular to the plane formed by the first direction D1 and the second direction D2.

Referring to FIG. 1, a substrate inspection apparatus SPC may include first and second load lock chambers RCB1 and RCB2, first and second storage chambers SCB1 and SCB2, first, second, and third process chambers PCB1, PCB2, and PCB3, first and second transfer chambers MCB1 and MCB2, and first and second thickness sensors MP1 and MP2.

A substrate SUB may be carried into the substrate inspection apparatus SPC through the first load lock chamber RCB1. After the substrate SUB is carried into the first load lock chamber RCB1, the first load lock chamber RCB1 may exhaust air present therein. Accordingly, the inside of the first load lock chamber RCB1 may be maintained in a state close to a vacuum in which residual air is minimized. For example, the pressure inside the first load lock chamber RCB1 may be about 50 mTorr (millitorr) or less. However, the embodiments of the present disclosure are not necessarily limited thereto.

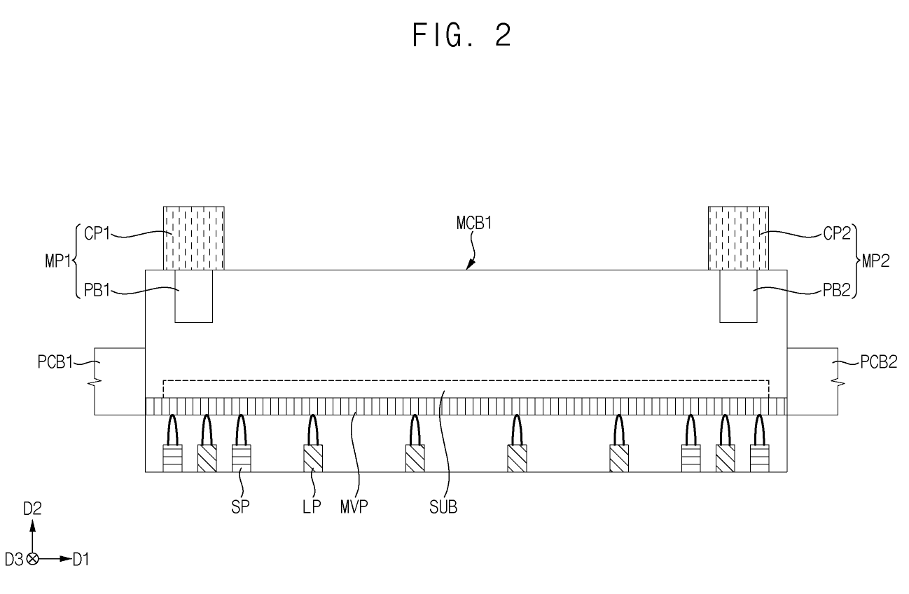

The first storage chamber SCB1 may be connected to the first load lock chamber RCB1. The first storage chamber SCB1 may be a chamber in which a substrate (e.g., the substrate SUB of FIG. 2) is temporarily stored before being transferred to the first, second, and third process chambers PCB1, PCB2, and PCB3. The pressure inside the first storage chamber SCB1 may be substantially the same as the pressure inside the first load lock chamber RCB1.

The first process chamber PCB1 may be connected to the first storage chamber SCB1. Accordingly, the substrate SUB transferred to the first storage chamber SCB1 may be transferred to the first process chamber PCB1. The first process chamber PCB1 may be a process chamber which performs a deposition process, an exposure process, an etching process, and the like on the substrate SUB. For example, a thin film and the like may be formed on the substrate SUB in the first process chamber PCB1.

The first transfer chamber MCB1 may connect the first process chamber PCB1 and the second process chamber PCB2. The substrate SUB having completed a deposition process in the first process chamber PCB1 may be transferred to the first transfer chamber MCB1. The first transfer chamber MCB1 may extend in the first direction D1.

Each of the first thickness sensor MP1 and the second thickness sensor MP2 may be disposed in the first transfer chamber MCB1. In FIG. 1, the first transfer chamber MCB1 is illustrated as including the first thickness sensor MP1 and the second thickness sensor MP2, but the first transfer chamber MCB1 may include one or three or more thickness sensors. In addition, in FIG. 1, the thickness sensors are illustrated as disposed only in the first transfer chamber MCB1, but the thickness sensors may also be disposed in the second transfer chamber MCB2.

In an embodiment, a thickness of the thin film deposited on the substrate SUB may be measured in the first transfer chamber MCB1. For example, each of the first thickness sensor MP1 and the second thickness sensor MP2 may measure the thickness of the thin film deposited on the substrate SUB. For example, the first transfer chamber MCB1 may be not only a chamber in which the substrate SUB is transferred from the first process chamber PCB1 to the second process chamber PCB2, but also a chamber which measures the thickness of the thin film deposited on the substrate SUB. The first thickness sensor MP1 and the second thickness sensor MP2 may completely inspect the substrate SUB passing through the first transfer chamber MCB1.

The second process chamber PCB2 may be connected to the first transfer chamber MCB1. After the thickness of the thin film is measured in the first transfer chamber MCB1, the substrate SUB may be transferred to the second process chamber PCB2. The second process chamber PCB2 may perform a deposition process on the substrate SUB. Thereafter, the substrate SUB may be sequentially transferred through the second transfer chamber MCB2 to the third process chamber PCB3. In FIG. 1, the substrate inspection apparatus SPC is illustrated as including the first, second, and third process chambers PCB1, PCB2, and PCB3, but the substrate inspection apparatus SPC may include two or fewer or four or more process chambers.

The third process chamber PCB3 may be connected to the second storage chamber SCB2, and the second load lock chamber RCB2 may be disposed at one side of the second storage chamber SCB2. For example, the substrate SUB having completed deposition processes and the like through the first, second, and third process chambers PCB1, PCB2, and PCB3 may be sequentially transferred through the second storage chamber SCB2 and the second load lock chamber RCB2 to be transferred outside a first auxiliary pin area SPA1.

In an embodiment, the first process chamber PCB1 may be a process chamber which deposits an inorganic film on the substrate SUB, the second process chamber PCB2 may be a process chamber which deposits an organic film, and the third process chamber PCB3 may be a process chamber which deposits an inorganic film. However, the embodiments of the present disclosure are not necessarily limited thereto. The first process chamber PCB1 may be a process chamber which deposits an organic film on the substrate SUB, the second process chamber PCB2 may be a process chamber which deposits an inorganic film, and the third process chamber PCB3 may be a process chamber which deposits an organic film.

FIG. 2 is a cross-sectional view illustrating an embodiment of a first transport chamber of FIG. 1.

Referring to FIGS. 1 and 2, the first transfer chamber MCB1 may include a transfer actuator MVP, lift pins LP, auxiliary pins SP, and the first and second thickness sensors MP1 and MP2.

The transfer actuator MVP may transfer the substrate SUB from the first process chamber PCB1 to the second process chamber PCB2. For example, the transfer actuator MVP may extend in the first direction D1. For example, the transfer actuator MVP may include a conveyor belt, a transfer chain, and the like. However, the embodiments of the present disclosure are not necessarily limited thereto.

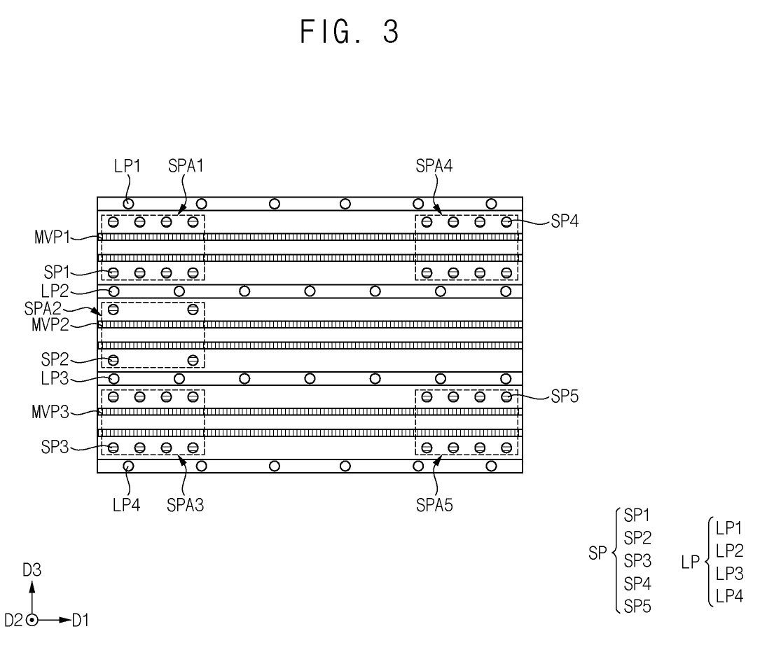

The lift pins LP may be disposed in the first transfer chamber MCB1 and may be disposed under the transfer actuator MVP in a cross-sectional view. The plurality of lift pins LP may be disposed under the transfer actuator MVP. For example, the lift pins LP may be spaced apart from each other in the first direction D1. The planar arrangement of the lift pins LP will be described later with reference to FIGS. 3, 4, and 5,

The auxiliary pins SP may be disposed in the first transfer chamber MCB1 and may be disposed under the transfer actuator MVP in a cross-sectional view. The plurality of auxiliary pins SP may be disposed under the transfer actuator MVP. For example, the auxiliary pins SP may overlap the first thickness sensor MP1 and/or the second thickness sensor MP2 in the plan view. The planar arrangement of the auxiliary pins SP will be described later with reference to FIGS. 3, 4, and 5, .

The first and second thickness sensors MP1 and MP2 may be disposed at one side of the first transfer chamber MCB1. As illustrated in FIG. 2, each of the first and second thickness sensors MP1 and MP2 may be spaced apart from the transfer actuator MVP in the second direction D2 and may be attached to an upper surface of the first transfer chamber MCB1.

The first thickness sensor MP1 may include a first probe PB1 which casts light onto the thin film on the substrate SUB and a first calculator CP1 which measures the thickness of the thin film. The second thickness sensor MP2 may include a second probe PB2 which casts light onto the thin film on the substrate SUB and a second calculator CP2 which measures the thickness of the thin film.

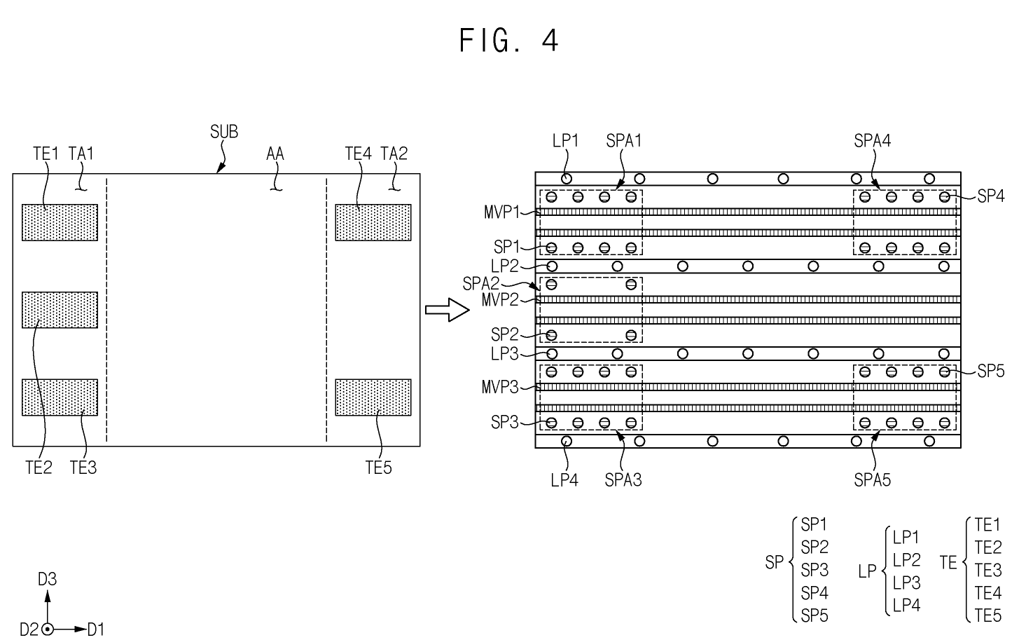

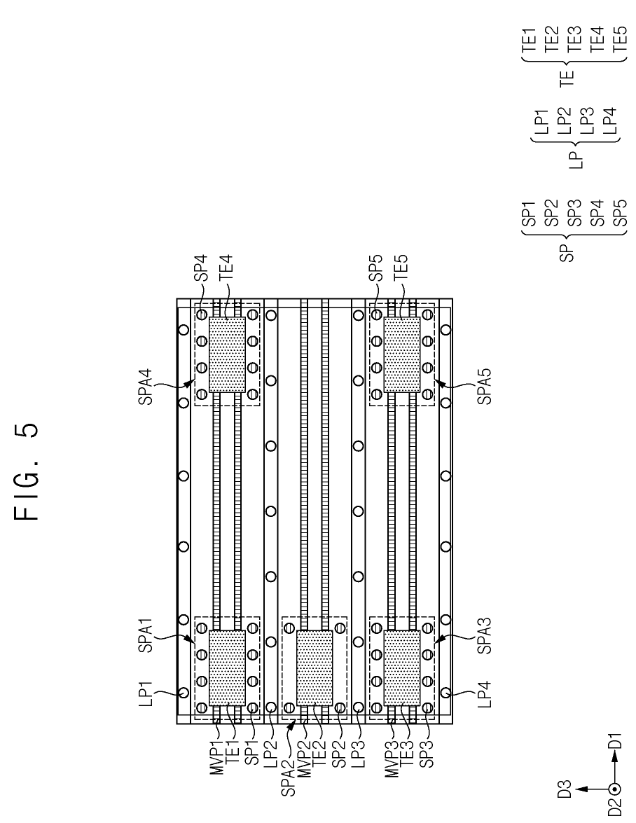

FIGS. 3, 4, and 5, are plan views illustrating lift pins, auxiliary pins of the first transfer chamber, and a substrate of FIG. 2. For example, FIG. 4 is a plan view illustrating which the substrate SUB is transferred from the first process chamber PCB1 to the first transfer chamber MCB1. FIG. 5 is a plan view illustrating which the substrate SUB is transferred to and seated in the first transfer chamber MCB1.

Referring to FIGS. 2 and 3, first, second, third, fourth, fifth, and fifth auxiliary pin areas SPA1, SPA2, SPA3, SPA4, and SPA5 may be defined in the first transfer chamber MCB1. The lift pins LP may include first, second, third, and fourth lift pins LP1, LP2, LP3, and LP4. The auxiliary pins SP may include first, second, third, fourth, and fifth auxiliary pins SP1, SP2, SP3, SP4, and SP5. The transfer actuator MVP may include first, second, and third transfer actuators MVP1, MVP2, and MVP3.

Each of the first, second, third, fourth, and fifth auxiliary pin areas SPA1, SPA2, SPA3, SPA4, and SPA5 may be defined at both sides of the first transfer chamber MCB1 along the first direction D1. For example, as illustrated in FIG. 3, the first, second, and third auxiliary pin areas SPA1, SPA2, and SPA3 may be defined at one side of the first transfer chamber MCB1 in an opposite direction of the first direction D1. In this case, the second auxiliary pin area SPA2 may be spaced apart from the first auxiliary pin area SPA1 in an opposite direction of the third direction D3, and the third auxiliary pin area SPA3 may be spaced apart from the second auxiliary pin area SPA2 in the opposite direction of the third direction D3. The fourth and fifth auxiliary pin areas SPA4 and SPA5 may be defined at one side of the first transfer chamber MCB1 in the first direction D1. In this case, the fifth auxiliary pin area SPA5 may be spaced apart from the fourth auxiliary pin area SPA4 in the opposite direction of the third direction D3.

In FIG. 3, the first transfer chamber MCB1 is illustrated as including five auxiliary pin areas SPA1, SPA2, SPA3, SPA4, and SPA5, but the embodiments of the present disclosure are not necessarily limited thereto. The first transfer chamber MCB1 may include one or more and ten or fewer auxiliary pin areas (within a range of 1 to 10, inclusive). Preferably, the first transfer chamber MCB1 may include three or more and eight or fewer auxiliary pin areas (within a range of 3 to 8, inclusive). In addition, in FIGS. 3, 4, and 5, the first, second, third, fourth, and fifth auxiliary pin areas SPA1, SPA2, SPA3, SPA4, and SPA5 are illustrated as having a rectangular shape, but each of the first, second, third, fourth, and fifth auxiliary pin areas SPA1, SPA2, SPA3, SPA4, and SPA5 may include planar shapes such as an ellipse or a polygon other than rectangular.

In an embodiment, the thickness sensors (e.g., the first and second thickness sensors MP1 and MP2) may correspond one-to-one with the auxiliary pin areas. For example, although two thickness sensors are illustrated in FIG. 2, in the case where five auxiliary pin areas are provided as illustrated in FIG. 3, five thickness sensors may be disposed. Accordingly, probes included in each of the thickness sensors may be disposed in five.

The first, second, third, fourth, and fifth auxiliary pin areas SPA1, SPA2, SPA3, SPA4, and SPA5 may include the first, second, third, fourth, and fifth auxiliary pins SP1, SP2, SP3, SP4, and SP5, respectively. For example, the first auxiliary pins SP1 may be disposed in the first auxiliary pin area SPA1, the second auxiliary pins SP2 may be disposed in the second auxiliary pin area SPA2, the third auxiliary pins SP3 may be disposed in the third auxiliary pin area SPA3, the fourth auxiliary pins SP4 may be disposed in the fourth auxiliary pin area SPA4, and the fifth auxiliary pins SP5 may be disposed in the fifth auxiliary pin area SPA5.

In an embodiment, the first, second, third, fourth, and fifth auxiliary pins SP1, SP2, SP3, SP4, and SP5 may be symmetrically disposed in the first, second, third, fourth, and fifth auxiliary pin areas SPA1, SPA2, SPA3, SPA4, and SPA5 in the plan view, respectively. For example, as illustrated in FIG. 3, the first auxiliary pins SP1 may be symmetrically disposed in the first auxiliary pin area SPA1 in the plan view. Since each of the first, second, third, fourth, and fifth auxiliary pins SP1, SP2, SP3, SP4, and SP5 is symmetrically disposed, sagging of the substrate SUB may be effectively prevented or reduced when supporting the substrate SUB.

In an embodiment, each of the first, second, third, fourth, and fifth auxiliary pins SP1, SP2, SP3, SP4, and SP5 may include four to eight auxiliary pins (a range of between 4 and 8, inclusive). For example, as illustrated in FIG. 3, each of the first auxiliary pins SP1, the third auxiliary pins SP3, the fourth auxiliary pins SP4, and the fifth auxiliary pins SP5 may include eight auxiliary pins. The second auxiliary pins SP2 may include four auxiliary pins. Accordingly, the total number of the first, second, third, fourth, and fifth auxiliary pins SP1, SP2, SP3, SP4, and SP5 may be 46 or more and 62 or fewer (a range of between 46 and 62, inclusive). However, the embodiments of the present disclosure are not necessarily limited thereto.

The first, second, third, and fourth lift pins LP1, LP2, LP3, and LP4 may be spaced apart from each other along the third direction D3. For example, the second lift pins LP2 may be spaced apart from the first lift pins LP1 in the opposite direction of the third direction D3, the third lift pins LP3 may be spaced apart from the second lift pins LP2 in the opposite direction of the third direction D3, and the fourth lift pins LP4 may be spaced apart from the third lift pins LP3 in the opposite direction of the third direction D3. In addition, each of the first, second, third, and fourth lift pins LP1, LP2, LP3, and LP4 may be spaced apart from the first, second, and third transfer actuators MVP1, MVP2, and MVP3 in the plan view.

Each of the first, second, third, and fourth lift pins LP1, LP2, LP3, and LP4 may be disposed at equal intervals in the first direction D1. For example, each of the first and fourth lift pins LP1 and LP4 may be six, and each of the second and third lift pins LP2 and LP3 may be seven. The first, second, third, and fourth lift pins LP1, LP2, LP3, and LP4 may be twenty-six in total. However, the embodiments of the present disclosure are not necessarily limited thereto.

Each of the first, second, and third transfer actuators MVP1, MVP2, and MVP3 may extend in the first direction D1. The first, second, and third transfer actuators MVP1, MVP2, and MVP3 may transfer the substrate SUB along the first direction D1. The first, second, and third transfer actuators MVP1, MVP2, and MVP3 may be spaced apart from each other along the third direction D3. For example, the second transfer actuator MVP2 may be spaced apart from the first transfer actuator MVP1 in the opposite direction of the third direction D3, and the third transfer actuator MVP3 may be spaced apart from the second transfer actuator MVP2 in the opposite direction of the third direction D3. In FIG. 3, the transfer actuator MVP is illustrated as including three transfer actuators MVP1, MVP2, and MVP3, but the embodiments of the present disclosure are not necessarily limited thereto.

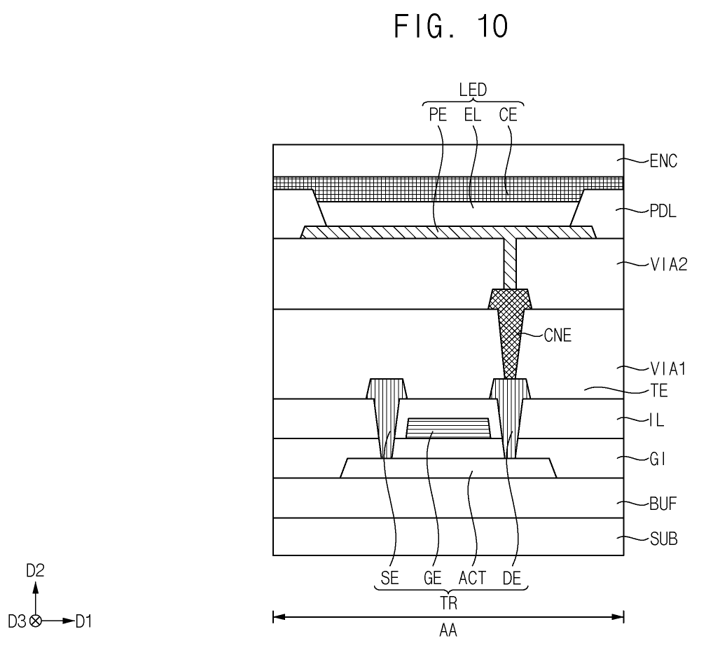

Referring also to FIGS. 1 and 4, the substrate SUB may be transferred from the first process chamber PCB1 to the first transfer chamber MCB1 by the transfer actuator MVP. The substrate SUB may include an active area AA in which a display panel (e.g., the display panel DP of FIG. 10) is disposed, and include a first test area TA1 and a second test area TA2 defined at both sides of the active area AA.

First, second, third, fourth, and fifth test elements TE1, TE2, TE3, TE4, and TE5 may be disposed in the first test area TA1 and the second test area TA2. For example, the first, second, and third test elements TE1, TE2, and TE3 may be disposed in the first test area TA1 of the substrate SUB, and the fourth and fifth test elements TE4 and TE5 may be disposed in the second test area TA2.

In an embodiment, a length of a long side of the substrate SUB in the first direction D1 may be about 1500 mm. A length of a short side of the substrate SUB in the second direction D2 may be about 925 mm. However, the embodiments of the present disclosure are not necessarily limited thereto.

Thus, the system may include multiple vacuum load lock chambers, storage chambers, and process chambers connected by transfer chambers containing transfer parts, lift pins, auxiliary pins, and thickness sensors. During operation, the substrate is transferred through these chambers along defined orthogonal directions, and while being supported by symmetrically arranged lift and auxiliary pins, the measuring parts cast light onto designated test elements in peripheral test areas of the substrate to measure the thickness of deposited thin films accurately as the substrate moves between deposition stages.

Referring also to FIG. 5, the substrate SUB may be transferred to the first transfer chamber MCB1 by the transfer actuator MVP. Each of the first, second, third, fourth, and fifth test elements TE1, TE2, TE3, TE4, and TE5 disposed on the substrate SUB may be disposed in the first, second, third, fourth, and fifth auxiliary pin areas SPA1, SPA2, SPA3, SPA4, and SPA5 of the first transfer chamber MCB1. For example, the first test element TE1 may be disposed in the first auxiliary pin area SPA1, the second test element TE2 may be disposed in the second auxiliary pin area SPA2, the third test element TE3 may be disposed in the third auxiliary pin area SPA3, the fourth test element TE4 may be disposed in the fourth auxiliary pin area SPA4, and the fifth test element TE5 may be disposed in the fifth auxiliary pin area SPA5.

In an embodiment, each of the first, second, third, fourth, and fifth test elements TE1, TE2, TE3, TE4, and TE5 may be surrounded by the first, second, third, fourth, and fifth auxiliary pins SP1, SP2, SP3, SP4, and SP5, respectively. For example, the first auxiliary pins SP1 may surround the first test element TE1 in the plan view and may be symmetrically disposed about the first test element TE1.

In FIGS. 3, 4, and 5, the auxiliary pin areas are illustrated as including five auxiliary pin areas SPA1, SPA2, SPA3, SPA4, and SPA5, but the embodiments of the present disclosure are not necessarily limited thereto. The auxiliary pin areas may be one or more and ten or fewer (a range of from 1 to 10, inclusive).

When the number of the auxiliary pin areas is one or more and ten or fewer (within a range from 1 to 10, inclusive), the number of test elements TE corresponding one-to-one to the auxiliary pin areas may be one or more and ten or fewer (within a range from 1 to 10, inclusive). In addition, the number of auxiliary pins SP disposed in the auxiliary pin areas may be four or more and eighty or fewer (range of from 4 to 8, inclusive). The embodiments illustrated in FIGS. 1, 2, 3, 4, and 5, are only one embodiment included in the present disclosure, and various embodiments beyond the described range may be considered.

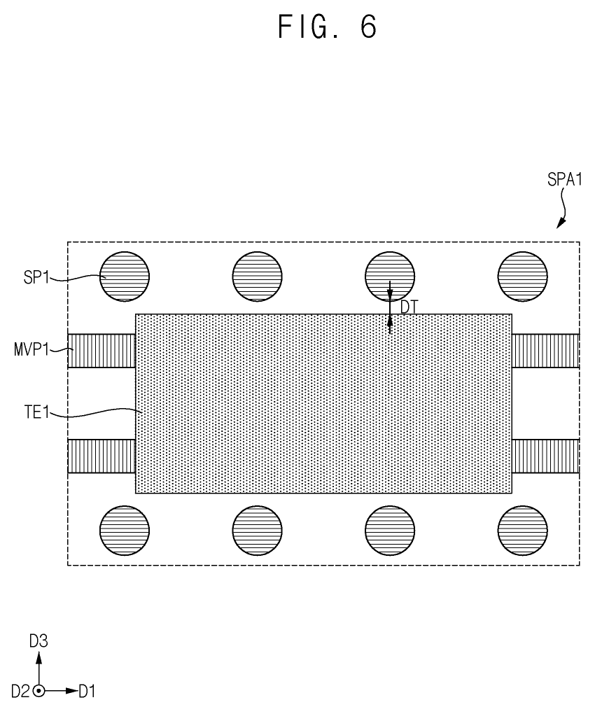

FIG. 6 is a plan view illustrating an enlarged view of a first auxiliary pin area of FIG. 5.

Referring to FIGS. 5 and 6, the first auxiliary pins SP1 may surround the first test element TE1 in the plan view. For example, the first auxiliary pins SP1 may be symmetrically disposed about the first test element TE1.

In an embodiment, a planar spacing distance DT between any one of the first auxiliary pins SP1 and the first test element TE1 may be about 20 mm or more and about 80 mm or less (within a range of 20 mm to 80 mm, inclusive). Preferably, the spacing distance DT between any one of the first auxiliary pins SP1 and the first test element TE1 may be about 30 mm or more and about 70 mm or less (within a range of 30 mm to 70 mm, inclusive). When the spacing distance DT is smaller than about 20 mm, electrical interference may occur between the first auxiliary pins SP1 and the first test element TE1, so that accurate measurement might not be achieved when measuring the thickness of the thin film. When the spacing distance DT is greater than about 80 mm, sagging of the substrate SUB may occur, which may reduce reliability when measuring the thickness of the thin film.

Although FIG. 6 describes the first test element TE1 and the first auxiliary pins SP1, spacing distances between each of the second, third, fourth, and fifth test elements TE2, TE3, TE4, and TE5 and each of the second, third, fourth, and fifth auxiliary pins SP2, SP3, SP4, and SP5 may be substantially the same as the spacing distance DT.

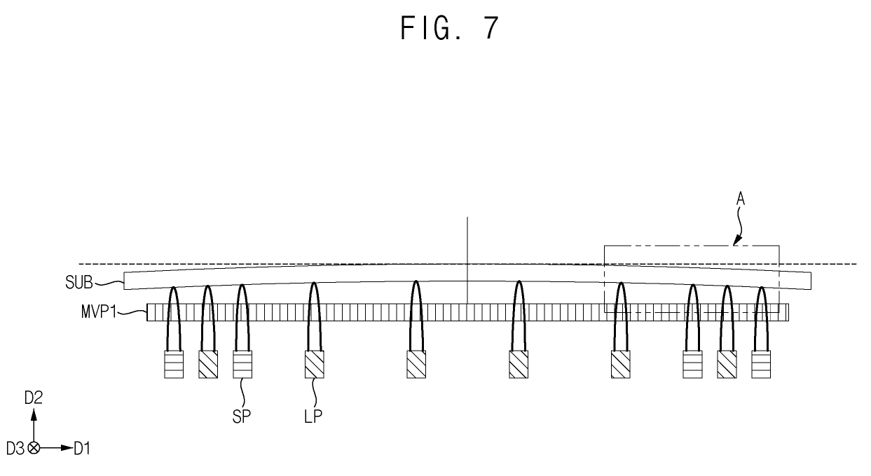

FIG. 7 is a cross-sectional view illustrating an embodiment in which lift pins and auxiliary pins of FIG. 2 support the substrate.

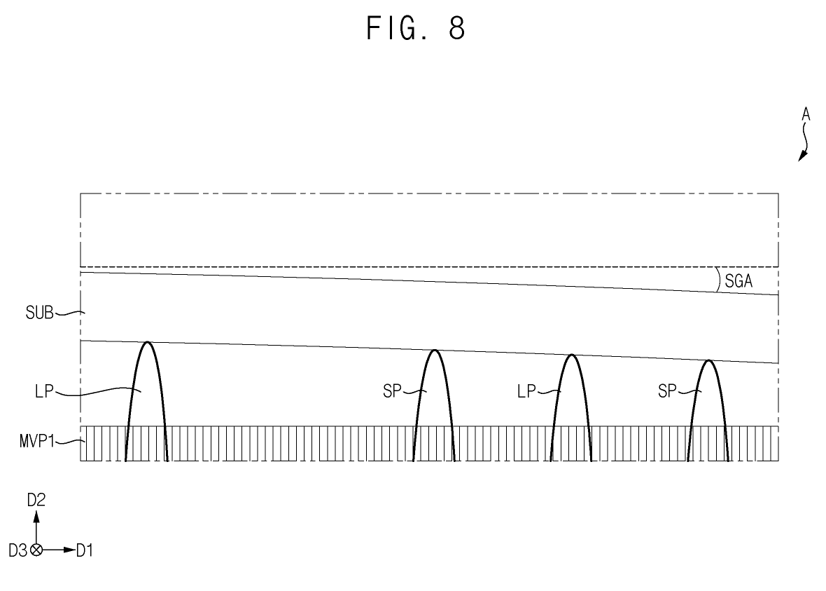

Referring to FIGS. 2, 7, and 8 , the substrate SUB transferred by the first transfer actuator MVP1 may be lifted in the second direction D2 by the lift pins LP and the auxiliary pins SP. For example, the substrate SUB supported by the first transfer actuator MVP1 may be lifted in the second direction D2 by the lift pins LP and the auxiliary pins SP.

When the substrate SUB is supported by the lift pins LP and the auxiliary pins SP, an end of the substrate SUB may sag in the opposite direction of the second direction D2. Due to sagging of the substrate SUB in the opposite direction of the second direction D2, an upper surface of the substrate SUB may have an angle SGA with respect to a horizontal reference plane that may be perpendicular/tangential to the gravitational direction. For example, the upper surface of the substrate SUB may have the angle SGA with a surface having a normal parallel to the second direction D2. When sagging occurs in the substrate SUB, the thickness of the thin film deposited on the substrate SUB might not be accurately measured.

In an embodiment, the angle SGA between the upper surface of the substrate SUB and the horizontal reference plane may be about 1.5 degrees or less. Preferably, the angle SGA between the upper surface of the substrate SUB and the horizontal reference plane may be about 1 degree or less. Since the angle SGA satisfies the above-described range, the thickness of the thin film deposited on the substrate SUB may be reliably measured.

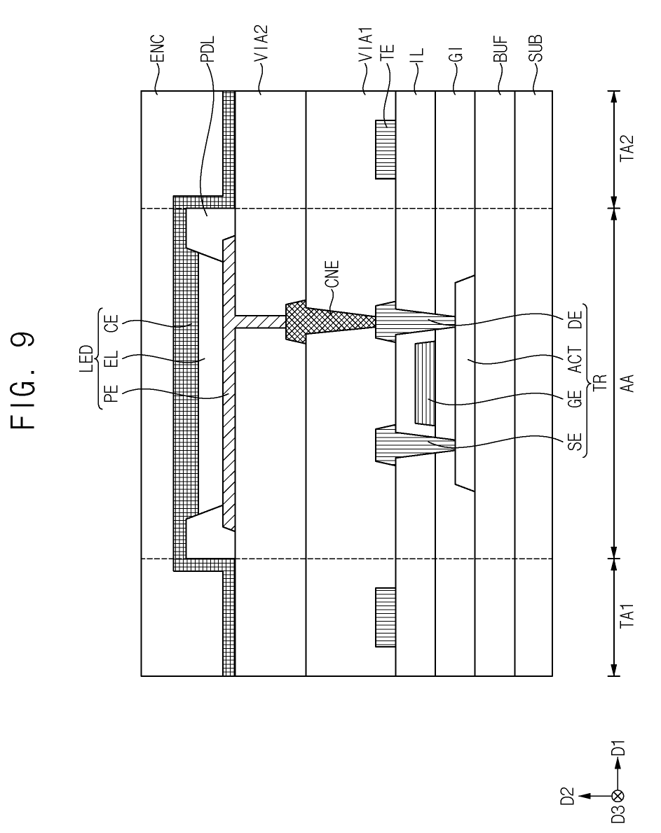

FIG. 9 is a cross-sectional view illustrating an embodiment of a display panel including the substrate of FIG. 7. FIG. 10 is a cross-sectional view illustrating an embodiment in which a test area is removed from the display panel of FIG. 9. The display panel DP illustrated in FIG. 9 illustrates a display panel after deposition is completed by the first auxiliary pin area SPA1 of FIG. 1. The display panel DP illustrated in FIG. 10 illustrates a display panel after the first and second test areas TA1 and TA2 are removed.

Referring to FIGS. 7 and 9, the display panel DP may include the substrate SUB, a display element layer DEL, and an encapsulation layer ENC. The display element layer DEL may include a buffer layer BUF, a gate insulating layer GI, a transistor TR, an interlayer insulating layer ILD, a connection electrode CNE, a first via layer VIA1, a second via layer VIA2, a light-emitting element LED, and a pixel defining layer PDL. The display panel DP may have an active area AA and the first and second test areas TA1 and TA2 located at both sides of the active area AA.

The transistor TR may include an active layer ACT, a gate electrode GE, a source electrode SE, and a drain electrode DE. The light-emitting element LED may include a pixel electrode PE, a light-emitting layer EL, and a common electrode CE.

The substrate SUB may include a glass substrate, a metal substrate, a plastic substrate, and the like. However, the embodiments of the present disclosure are not necessarily limited thereto, and the substrate SUB may be an inorganic layer, an organic layer, or a composite material layer.

The buffer layer BUF may be disposed on the substrate SUB. The buffer layer BUF may prevent impurities such as oxygen and moisture from penetrating into an upper portion of the substrate SUB through the substrate SUB. The buffer layer BUF may include an inorganic insulating material.

The active layer ACT may be disposed on the buffer layer BUF. The active layer ACT may include an oxide semiconductor, a silicon semiconductor, or an organic semiconductor. For example, the oxide semiconductor may include at least one oxide of indium (In), gallium (Ga), tin (Sn), zirconium (Zr), vanadium (V), hafnium (Hf), cadmium (Cd), germanium (Ge), chromium (Cr), titanium (Ti), and zinc (Zn). The silicon semiconductor may include amorphous silicon, polycrystalline silicon, and the like. The active layer ACT may include a source region, a drain region, and a channel region located between the source region and the drain region.

The gate insulating layer GI may be disposed on the buffer layer BUF. For example, the gate insulating layer GI may cover the active layer ACT on the buffer layer BUF. The gate insulating layer GI may include an inorganic insulating material. In an embodiment, the gate insulating layer GI may be entirely disposed in the active area AA. In an embodiment, the gate insulating layer GI may be disposed only under the gate electrode GE.

The gate electrode GE may be disposed on the gate insulating layer GI. The gate electrode GE may at least partially overlap the channel region of the active layer ACT. The gate electrode GE may include a conductive material such as a metal, an alloy, a conductive metal nitride, a conductive metal oxide, a transparent conductive material, and the like. Examples of the conductive material which can be used for the gate electrode GE may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), an alloy containing aluminum, an alloy containing silver, an alloy containing copper, an alloy containing molybdenum, aluminum nitride (AlN), tungsten nitride (WN), titanium nitride (TiN), chromium nitride (CrN), tantalum nitride (TaN), strontium ruthenium oxide (SrRuO), zinc oxide (ZnO), indium tin oxide (ITO), tin oxide (SnO), indium oxide (InO), gallium oxide (GaO), indium zinc oxide (IZO), and the like. These may be used alone or in combination with each other. Alternatively, the gate electrode GE may have a single-layer structure or a multi-layer structure including a plurality of conductive layers.

The interlayer insulating layer ILD may be disposed on the gate electrode GE. For example, the interlayer insulating layer ILD may be disposed on the gate insulating layer GI and may cover the gate electrode GE on the gate insulating layer GI. The interlayer insulating layer ILD may include an inorganic insulating material. In an embodiment, the interlayer insulating layer ILD may be entirely disposed in the active area AA.

The source electrode SE and the drain electrode DE may be disposed on the interlayer insulating layer ILD. The source electrode SE and the drain electrode DE may be connected to the active layer ACT, respectively. For example, the source electrode SE may contact the source region of the active layer ACT, and the drain electrode DE may contact the drain region of the active layer ACT. Each of the source electrode SE and the drain electrode DE may include a conductive material. The active layer ACT, the gate electrode GE, the source electrode SE, and the drain electrode DE may form the transistor TR.

The test element TE may be further disposed on the interlayer insulating layer ILD. For example, the test element TE may be disposed in the first and second test areas TA1 and TA2, and may be disposed in the same layer as the source electrode SE and the drain electrode DE. For example, the first, second, and third test elements (e.g., the first, second, and test elements TE1, TE2, and TE3 of FIG. 4) may be disposed in the first test area TA1, and the fourth and fifth test elements (e.g., the fourth and fifth test elements TE4 and TE5 of FIG. 4) may be disposed in the second test area TA2.

In an embodiment, the source electrode SE and the drain electrode DE may include the same material as the test element TE. For example, the test element TE may be formed simultaneously in the same process as the source electrode SE and the drain electrode DE. However, the embodiments of the present disclosure are not necessarily limited thereto. The test element TE may also be formed in the same process as the common electrode CE.

The first via layer VIA1 may be disposed on the source electrode SE and the drain electrode DE. For example, the first via layer VIA1 may be disposed on the interlayer insulating layer ILD, and may cover the source electrode SE, the drain electrode DE, and the test element TE on the interlayer insulating layer ILD. The first via layer VIA1 may include an organic insulating material.

The connection electrode CNE may be disposed on the first via layer VIA1. The connection electrode CNE may deliver a signal transferred from the transistor TR to the light-emitting element LED. The connection electrode CNE may include a conductive material such as a metal, an alloy, a metal nitride, a conductive metal oxide, a transparent conductive material, and the like. These may be used alone or in combination with each other. However, the embodiments of the present disclosure are not necessarily limited thereto.

The second via layer VIA2 may be disposed on the connection electrode CNE. For example, the second via layer VIA2 may be disposed on the first via layer VIA1 and may cover the connection electrode CNE. The second via layer VIA2 may include substantially the same material as the first via layer VIA1.

The pixel electrode PE may be disposed on the second via layer VIA2. The pixel electrode PE may include a conductive material. The pixel electrode PE may be connected to the drain electrode DE through the connection electrode CNE. Accordingly, the pixel electrode PE may be electrically connected to the transistor TR.

The pixel defining layer PDL may be disposed on the pixel electrode PE. For example, the pixel defining layer PDL may expose at least a portion of the pixel electrode PE. The pixel defining layer PDL may include an inorganic insulating material or an organic insulating material.

The light-emitting layer EL may be disposed on the pixel electrode PE. In an embodiment, the light-emitting layer EL may be disposed in an opening defined by the pixel defining layer PDL. For example, the light-emitting layer EL may be surrounded by the pixel defining layer PDL. In an embodiment, the light-emitting layer EL may also be disposed on the pixel defining layer PDL. The light-emitting layer EL may include at least one of an organic light-emitting material and quantum dots. However, the embodiments of the present disclosure are not necessarily limited thereto.

The common electrode CE may be disposed on the light-emitting layer EL. The common electrode CE may also be disposed on the pixel defining layer PDL. For example, the common electrode CE may be continuously disposed on the light-emitting layer EL and the pixel defining layer PDL. The common electrode CE may include a conductive material. The light-emitting layer EL may emit light based on a voltage difference between the pixel electrode PE and the common electrode CE.

The encapsulation layer ENC may be disposed on the common electrode CE. The encapsulation layer ENC may include at least one inorganic encapsulation layer and at least one organic encapsulation layer. In an embodiment, the inorganic encapsulation layer and the organic encapsulation layer may be alternately disposed. For example, the organic encapsulation layer may include a polymer cured material such as polyacrylate, epoxy resin, silicone resin, and the like. For example, the inorganic encapsulation layer may include silicon oxide, silicon nitride, silicon carbide, aluminum oxide, tantalum oxide, hafnium oxide, zirconium oxide, titanium oxide, and the like.

In an embodiment, the substrate inspection apparatus (e.g., the first auxiliary pin area SPA1 of FIG. 1) may measure the thickness of the inorganic encapsulation layer or the organic encapsulation layer included in the encapsulation layer ENC. For example, the first and second thickness sensors MP1 and MP2 of the first auxiliary pin area SPA1 may measure the thickness of the inorganic encapsulation layer or the organic encapsulation layer included in the encapsulation layer ENC. The first and second calculators (e.g., the first and second calculators CP1 and CP2 of FIG. 2) may determine whether the thickness of the encapsulation layer ENC is equal to a preset thickness.

Thus, the substrate, with multiple test elements, may be positioned within corresponding auxiliary pin areas of the transfer chamber so each test element is symmetrically surrounded and supported by auxiliary pins to prevent sagging during thickness measurement. The spacing between each test element and its surrounding auxiliary pins may be carefully controlled, for example, between 30 and 70 mm, to balance electrical isolation and mechanical stability, ensuring accurate optical thickness measurements while maintaining a substrate tilt of no more than 1.5° from horizontal. The display panel may be formed on the substrate to include multiple functional layers such as transistors, electrodes, and encapsulation layers, and that the inspection apparatus measures the thickness of these inorganic or organic encapsulation layers using optical sensors to verify conformity to preset specifications.

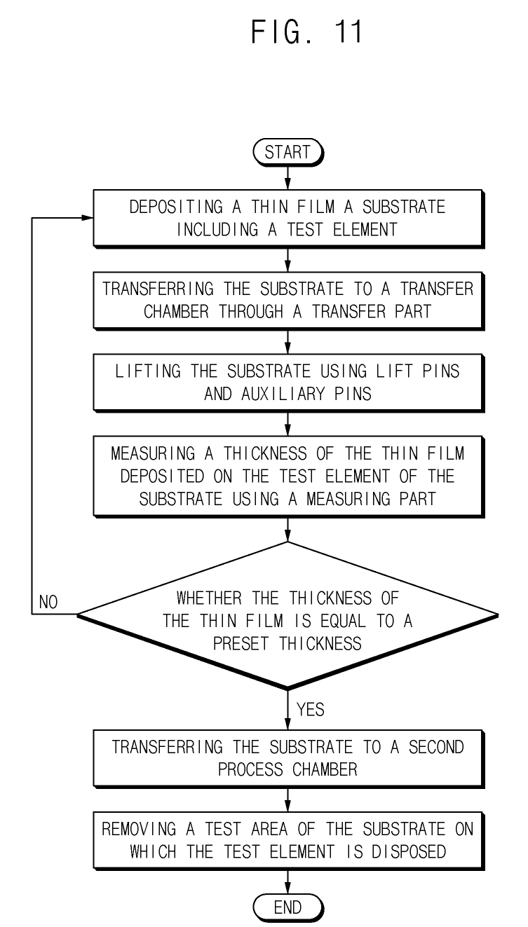

FIG. 11 is a flowchart illustrating an embodiment of a method of inspecting the substrate of the substrate inspection apparatus of FIG. 1.

Referring to FIGS. 1, 2, 3, 4, 5, 6, 7, 8, 9, 10, and 11, a thin film may be deposited on the substrate SUB in the first process chamber PCB1. The thin film may be one of an inorganic thin film layer or an organic thin film layer of the thin film encapsulation layer ENC illustrated in FIG. 9. Alternatively, the thin film may refer to one of the first via layer VIA1 or the second via layer VIA2.

After depositing the thin film on the substrate SUB, the substrate SUB may be transferred to the first transfer chamber MCB1 through the transfer actuator MVP. The substrate SUB transferred into the first transfer chamber MCB1 may be lifted by the lift pins LP and the auxiliary pins SP. In this case, compared to a case where the substrate SUB is supported only by the lift pins LP, the occurrence of sagging of the substrate SUB may be prevented or reduced by supporting the substrate SUB with the auxiliary pins SP.

The substrate SUB lifted by the lift pins LP and the auxiliary pins SP may have a thickness of the thin film measured through the first and second thickness sensors MP1 and MP2. In an embodiment, the first and second probes PB1 and PB2 may cast light onto the test element TE included in the substrate SUB to measure the thickness of the thin film. However, the embodiments of the present disclosure are not necessarily limited thereto. The first and second probes PB1 and PB2 may also cast electrons onto the test element TE to measure the thickness of the thin film.

Since the test element TE is disposed on the substrate SUB, light emitted from the first and second thickness sensors MP1 and MP2 may be reflected by the test element TE, so that the thickness of the thin film deposited on the test element TE may be selectively measured.

In this case, the first and second calculators CP1 and CP2 may determine whether the measured thickness of the thin film is equal to the preset thickness. For example, when the measured thickness of the thin film is different from the preset thickness, the substrate SUB may be returned to the first process chamber PCB1. In another example, when the measured thickness of the thin film is equal to the preset thickness, the substrate SUB may be transferred to the second process chamber PCB2.

Thereafter, thin film processes may be sequentially performed on the substrate SUB in the second process chamber PCB2 and the third process chamber PCB3. The substrate SUB having completed the thin film processes sequentially may be carried out of the first auxiliary pin area SPA1 through the second storage chamber SCB2 and the second load lock chamber RCB2. Thereafter, as illustrated in FIG. 10, the first and second test areas TA1 and TA2 of the substrate SUB may be removed.

As described with reference to FIGS. 1 and 11, when the substrate SUB is supported by the lift pins LP, sagging of the substrate SUB may be prevented or reduced by the auxiliary pins SP. As a result, the thickness of the thin film deposited on the substrate SUB may be measured more accurately. For example, as the auxiliary pins SP additionally support the substrate SUB, the reliability of the substrate inspection apparatus SPC measuring the thickness of the thin film may be improved.

In addition, since the thickness of the thin film is measured during transfer, rather than after all processes are completed, the substrate SUB may be returned and re-processed when the thickness of the thin film differs from the preset thickness. As a result, time and cost efficiency may be increased for the substrate inspection apparatus SPC.

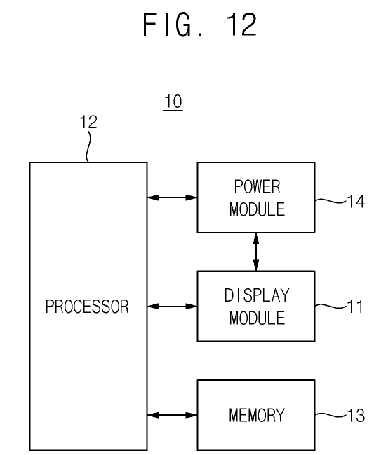

FIG. 12 is a block diagram illustrating an electronic device according to an embodiment of the present disclosure.

Referring to FIG. 12, the display device DD, according to embodiments, may be applied to various electronic devices 10. The electronic device 10, according to an embodiment, includes the above-described display device DD and may further include a module or device having an additional function other than the display device DD.

The electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

Data information necessary for operation of the processor 12 or the display module 11 may be stored in the memory 13. When the processor 12 executes an application stored in the memory 13, an image data signal and/or an input control signal may be delivered to the display module 11, and the display module 11 may process the received signal and output image information through a display screen.

The power module 14 may convert power supplied by a power supply module such as a power adapter or a battery device. For example, the power module 14 may include a power conversion module which generates power necessary for operation of the electronic device 10.

At least one of the components of the above-described electronic device 10 may be included in the display device according to the embodiments. In addition, some of the individual modules included functionally in one module may be included in the display device, and others may be provided separately from the display device. For example, the display device DD may include the display module 11, and the processor 12, the memory 13, and the power module 14 may be provided in the form of other devices in the electronic device 10, rather than in the display device DD.

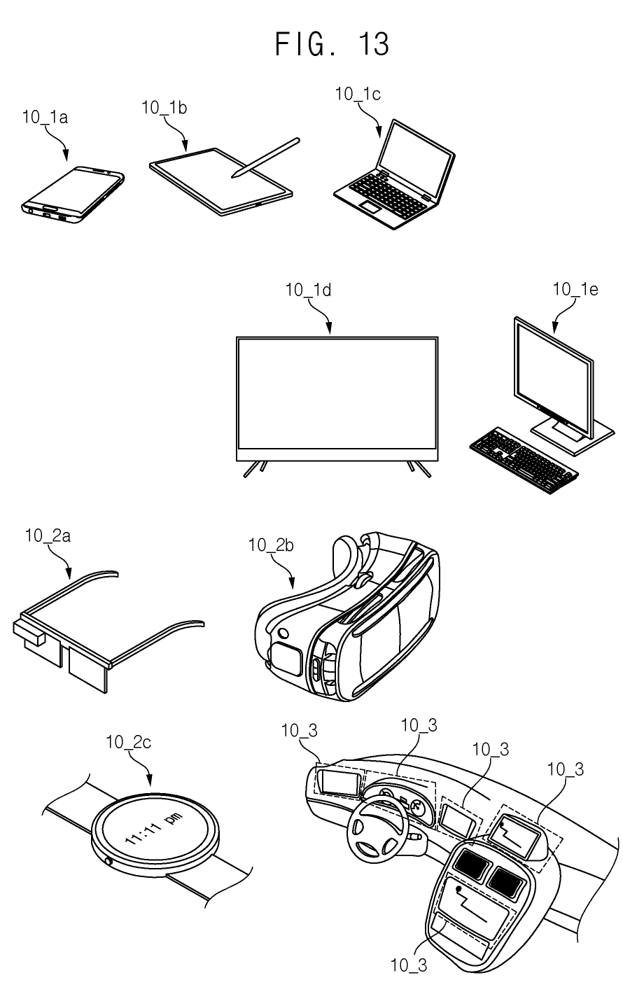

FIG. 13 is a schematic diagram of an electronic device according to various embodiments of FIG. 12.

Referring to FIGS. 12 and 13, various electronic devices 10 to which the display device DD according to embodiments is applied may include image display electronic devices such as a smartphone 10_1a, a tablet computer 10_1b, a laptop/notebook computer 10_1c, a TV 10_1d, and a computer monitor 10_1e. In addition, wearable electronic devices including a display module such as smart glasses 10_2a, a head-mounted display 10_2b, and a smart watch 10_2c, and vehicle electronic devices 10_3 including a display module such as a center information display (CID) disposed in an instrument panel, a center fascia, and a dashboard of an automobile, and a room mirror display may also be included.

The present disclosure may be applied to a display device and an electronic device including the same. For example, the present disclosure may be applied to a high-resolution smartphone, a mobile phone, a smart pad, a smart watch, a tablet computer, a vehicle navigation system, a television, a computer monitor, a laptop/notebook computer, and the like.

While the present disclosure has been described with reference to exemplary embodiments, it will be understood by those skilled in the art that various modifications and changes may be made within the scope not departing from the spirit and scope of the present disclosure.

What is claimed is:

1. An inspection apparatus, comprising:
a transfer chamber configured to receive a substrate including a test element and a thin film deposited on an upper surface of the test element ;
a transfer actuator disposed in the transfer chamber and configured to move the substrate in a first direction;
a plurality of lift pins disposed under the transfer actuator in a cross-sectional view, configured to support the substrate in a second direction intersecting the first direction, and spaced apart from the transfer actuator in a plan view;
a plurality of auxiliary pins disposed under the transfer actuator in the cross-sectional view, configured to support the substrate in the second direction, surrounding the test element of the substrate in the plan view, and symmetrically disposed about the test element; and
a thickness sensor including a plurality of probes which are disposed at one side of the transfer chamber and are configured to measure a thickness of the thin film deposited on the test element of the substrate.

2. The inspection apparatus of claim 1, wherein each of the plurality of auxiliary pins is spaced apart from the test element by a distance within a range of from about 20 nm to about 80 nm, in the plan view.

3. The inspection apparatus of claim 1, wherein the each of the plurality of auxiliary pins are spaced apart from the transfer actuator in the plan view.

4. The inspection apparatus of claim 1, wherein a number of the plurality of auxiliary pins is within a range from 4 to 80.

5. The inspection apparatus of claim 1, wherein the test element includes a first test element and a second test element spaced apart from the first test element in the plan view, and
wherein the plurality of auxiliary pins include a first auxiliary pin symmetrically disposed about the first test element and a second auxiliary pin symmetrically disposed about the second test element.

6. The inspection apparatus of claim 5, wherein a number of each of the first auxiliary pin and the second auxiliary pin is within a range from 4 to 8.

7. The inspection apparatus of claim 1, further comprising:
a first process chamber disposed at one side of the transfer chamber; and
a second process chamber disposed at another side of the transfer chamber.

8. The inspection apparatus of claim 7, wherein the first process chamber is a process chamber configured for depositing an inorganic film and the second process chamber is a process chamber configured for depositing an organic film.

9. The inspection apparatus of claim 1, wherein the thickness sensor is configured either for measuring an inorganic film or an organic film.

10. The inspection apparatus of claim 1, wherein a number of the test element is within a range of between 1 and 10, and
wherein the plurality of probes of the thickness sensor correspond one-to-one to the test element of the substrate.

11. The inspection apparatus of claim 1, wherein the thickness sensor casts light through the plurality of probes.

12. A method of inspection, comprising:
depositing a thin film on a substrate, that includes a test element, in a first process chamber;
transferring the substrate to a transfer chamber using a transfer actuator;
lifting the substrate, using a plurality of lift pins, that are spaced apart from the transfer actuator in a plan view, and a plurality of auxiliary pins surrounding the test element and symmetrically disposed about the test element; and
measuring a thickness of the thin film deposited on the test element of the substrate using a thickness sensor.

13. The method of inspection of claim 12, wherein in the lifting of the substrate using the plurality of lift pins and the plurality of auxiliary pins,
each of the plurality of auxiliary pins is spaced apart from the test element of the substrate by a distance within a range of from about 20 nm to about 80 nm, in the plan view.

14. The method of inspection of claim 13, wherein after the lifting of the substrate using the plurality of lift pins and the plurality of auxiliary pins,
an angle formed between one side of the substrate and a horizontal reference plane is less than or equal to about 1.5 degrees.

15. The method of inspection of claim 12, wherein in the measuring of the thickness of the thin film,
the thickness sensor measures the thickness of the thin film by casting light on the test element of the substrate.

16. The method of inspection of claim 12, wherein after the measuring the thickness of the thin film, the method further comprises:
transferring the substrate to a second process chamber when that the thickness of the thin film is measured to be equal to a preset thickness.

17. The method of inspection of claim 16, wherein after the transferring of the substrate to the second process chamber, the method further comprises:
removing a test area, on which the test element of the substrate is disposed, from the substrate.

18. The method of inspection of claim 16, wherein the first process chamber is a process chamber for depositing an inorganic film and the second process chamber is a process chamber for depositing an organic film.

19. The method of inspection of claim 16, wherein after the transferring of the substrate to the second process chamber, the method further comprises:
returning the substrate to the first process chamber when the thickness of the thin film is measured as being different from a preset thickness.

20. An electronic device, comprising:
a display device; and
a processor configured to drive the display device,
wherein an inspection apparatus is configured to measure the display device, the inspection apparatus including:
a transfer chamber through which a substrate, including a test element and a thin film deposited on an upper surface of the test element, is transferred;
a transfer actuator disposed in the transfer chamber and configured to move the substrate in a first direction;
a plurality of lift pins disposed under the transfer actuator in a cross-sectional view, configured to support the substrate in a second direction intersecting the first direction, and spaced apart from the transfer actuator in a plan view;
a plurality of auxiliary pins disposed under transfer actuator in the cross-sectional view, configured to support the substrate in the second direction, surrounding the test element of the substrate in the plan view, and symmetrically disposed about the test element; and
a thickness sensor including a plurality of probes which are disposed at one side of the transfer chamber and configured to measure a thickness of the thin film deposited on the test element of the substrate.
